(19) United States
(12) Patent Application Publication
(10) Pub. No.: US 2016/0284807 A1
(43) Pub. Date: Sep. 29, 2016

(54) METHOD OF FORMATION OF A SUBSTRATE OF THE SOI, IN PARTICULAR THE FDSOI, TYPE ADAPTED TO TRANSISTORS HAVING GATE DIELECTRICS OF DIFFERENT THICKNESSES, CORRESPONDING SUBSTRATE AND INTEGRATED CIRCUIT

(71) Applicants: STMicroelectronics (Crolles 2) SAS, Crolles (FR); STMicroelectronics SA, Montrouge (FR)

(72) Inventors: David Petit, Grenoble (FR); Frederic Monsieur, Pontcharra (FR); Xavier Federspiel, Le Versoud (FR); Gregory Bidal, Grenoble (FR)

(73) Assignees: STMICROELECTRONICS (CROLLES 2) SAS, Crolles (FR); STMICROELECTRONICS SA, Montrouge (FR)

(21) Appl. No.: 14/930,324

(22) Filed: Nov. 2, 2015

(30) Foreign Application Priority Data
Mar. 27, 2015 (FR) 1552623

(51) Int. Cl. H01L 29/423; H01L 21/8234; H01L 29/10; H01L 27/088; H01L 29/78; H01L 29/06; H01L 21/84; H01L 27/12

(52) U.S. Cl. CPC H01L 29/42364; H01L 21/84; H01L 21/823412; H01L 21/823462; H01L 27/1203; H01L 27/088; H01L 29/7838; H01L 29/0653; H01L 29/1033

(57) ABSTRACT

A substrate of the silicon-on-insulator type is formed from an initial substrate of the silicon-on-insulator type having a semiconductor film on top of a buried insulating layer itself situated on top of a carrier substrate. A localized modification of a thickness of the semiconductor film is made so as to form a semiconductor film having different thicknesses in different regions.

### PRIORITY CLAIM

This application claims priority from French Application for Patent No. 1552623 filed Mar. 27, 2015, the disclosure of which is incorporated by reference.

### TECHNICAL FIELD

The invention relates to integrated circuits, and more particularly to the formation of thin films of different thicknesses, starting from the same substrate of the silicon-on-insulator type commonly denoted by those skilled in the art under the acronym “SOI”, and more particularly to a substrate of the Fully-Depleted Silicon-On-Insulator type known by those skilled in the art under the acronym “FDSOI”.

### BACKGROUND

A substrate of the silicon-on-insulator type generally comprises a semiconductor film, for example of silicon or of an alloy of silicon, with a uniform thickness, resting on a buried insulating layer, commonly denoted by the acronym “BOX” (“Buried-OXide”) itself situated on top of a carrier substrate, for example a semiconductor well.

Particularly in an FDSOI technology, the semiconductor film is fully depleted which ensures a good electrostatic control.

Generally speaking, the semiconductor film is very thin, for example of the order of a few nanometers. The buried insulating layer is furthermore generally very thin, of the order of twenty nanometers.

However, in some applications, it may be necessary to form, on the same SOI or FDSOI substrate transistors having gate oxides of different thicknesses, for example transistors with a thin gate oxide and transistors with a thick gate oxide in order to withstand high voltages, for example of the order of several volts.

Furthermore, the hot-carrier reliability (HCI: Hot Carrier Injection) of the transistors is highly dependent on the thickness of the thin film, which is the same over the whole substrate. The degradation will be worse as the thickness of the thin film is reduced and made worse by high voltages.

Accordingly, for such transistors, there is always a compromise to be reached between the HCI reliability and the electrostatic control.

### SUMMARY

According to one embodiment and its implementation, the aim is to improve this compromise for all transistors, for example in the case of transistors with a thick gate oxide formed jointly with transistors with a thin gate oxide on the same SOI substrate, in particular an FDSOI substrate.

According to one embodiment, the formation is provided of thin films of different thicknesses on the same substrate of the SOI type.

According to one aspect, a method is provided comprising the formation of a substrate of the silicon-on-insulator type starting from an initial substrate of the silicon-on-insulator type having a semiconductor film on top of a buried insulating layer itself situated on top of a carrier substrate.

The method according to this aspect comprises at least one localized modification of the thickness of the semiconductor film in such a manner as to form a semiconductor film having different thicknesses in different regions.

According to one possible variant, the at least one localized modification of the film comprises a masking of the semiconductor film in at least a first region by a mask, a formation in at least a second region of the semiconductor film of at least one protection layer consuming a part of the semiconductor film, for example a layer of the PADOX (PAD OXide) type according to an acronym well known to those skilled in the art, and the removal of the mask and of the protection layer.

According to another possible variant, the at least one localized modification can comprise the formation of a protection layer on the semiconductor film, for example a layer of the PADOX type, the removal of the protection layer in at least a first region of the semiconductor film, at least one epitaxy of the silicon type on the semiconductor film in the first region at least, and the removal of the protection layer in a second region.

The method can furthermore comprise the formation of transistors with gate oxides of different thicknesses on the semiconductor film in such a manner as to form at least a first transistor with a gate dielectric having a first thickness of dielectric, for example a transistor with a thin gate oxide, in a region where the semiconductor film has a first thickness of film and at least a second transistor with a gate dielectric having a second thickness of dielectric, greater than the first thickness of dielectric, for example a transistor with a thick gate oxide, in another region where the semiconductor film has a second thickness of film greater than the first thickness of film.

The substrate may advantageously be of the fully-depleted silicon-on-insulator (FDSOI) type.

According to another aspect, a substrate of the silicon-on-insulator type is provided comprising a semiconductor film having different thicknesses in different regions and resting on the same buried insulating layer itself situated on top of the same carrier substrate.

The substrate may for example be of the fully-depleted silicon-on-insulator type.

According to yet another aspect, an integrated circuit is provided comprising the substrate of the silicon-on-insulator type defined hereinbefore, at least a first transistor with a gate dielectric having a first thickness of dielectric in a region where the semiconductor film has a first thickness of film and at least a second transistor with a gate dielectric having a second thickness of dielectric greater than the first thickness of dielectric in another region where the semiconductor film has a second thickness of film greater than the first thickness of film.

### BRIEF DESCRIPTION OF THE DRAWINGS

Other advantages and characteristics of the invention will become apparent upon examining the detailed description of non-limiting embodiments and their implementation, and the appended drawings in which:

FIGS. 1 to 11 illustrate schematically embodiments of the invention and their implementation.

### DETAILED DESCRIPTION

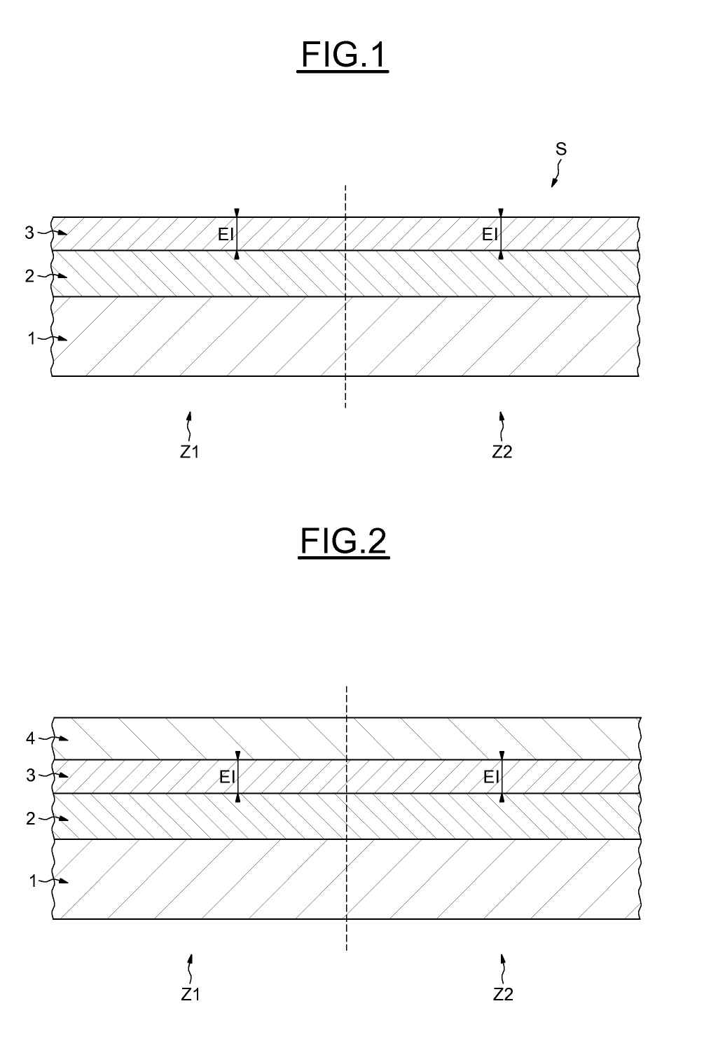

FIG. 1 illustrates an initial substrate S of the fully-depleted silicon-on-insulator (FDSOI) type comprising a semiconductor film 3 on top of a buried insulating layer 2 (BOX) itself resting on a carrier substrate 1 which may for example be a semiconductor well.

It should be noted that the initial thickness EI of the semiconductor film 3 is identical in first and second regions Z1 and Z2.

On this initial substrate S, a layer 4 of hard mask, for example made of tetraethyl orthosilicate (TEOS), is first of all deposited in the first and second regions Z1 and Z2 (FIG. 2).

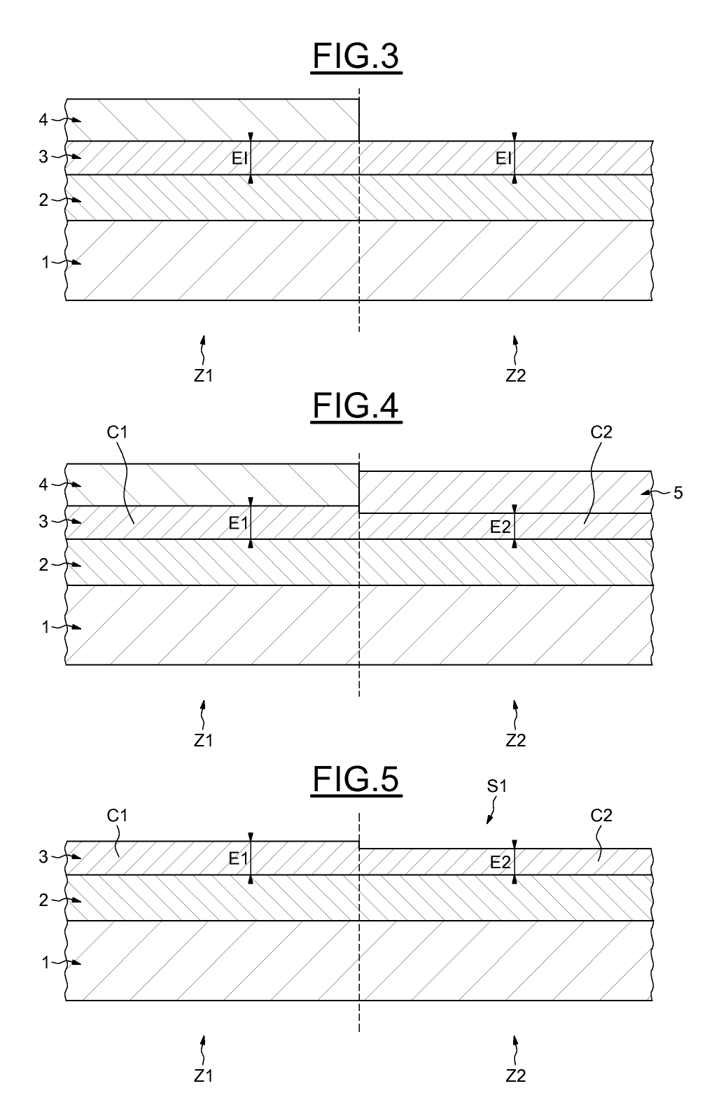

Using a conventional photolithography with an etch mask and subsequently a wet etch adapted to the hard mask 4, for example an HF etch (based on hydrofluoric acid (HF)), the layer of TEOS hard mask 4 in the second region Z2 may be etched down to the semiconductor film 3 (FIG. 3).

Generally speaking, in CMOS fabrication processes, carrying out processing operations on bare silicon is avoided and the latter is protected by a layer of oxide commonly denoted by those skilled in the art using the term PADOX.

Accordingly, in this embodiment, the semiconductor film 3 can be covered in the second region Z2 by a protection layer 5, for example of the PADOX type. This formation of the PADOX layer 5 illustrated in FIG. 4 may be carried out in an oven.

This PADOX layer 5 consumes a part of the semiconductor film 3 during its formation, which reduces the thickness of the semiconductor film 3 in the second region Z2 to a thickness E2.

Then, as illustrated in FIG. 5, the layer of hard mask 4, together with the protection layer 5, can be eliminated for example by a single HF etch step.

Accordingly, a substrate S1 of the SOI type can be formed comprising a semiconductor film 3 of different thicknesses (E1>E2) in the various regions Z1 and Z2 (FIG. 5). The difference in thickness (E1−E2) may be of the order of 5 nanometers or less or more.

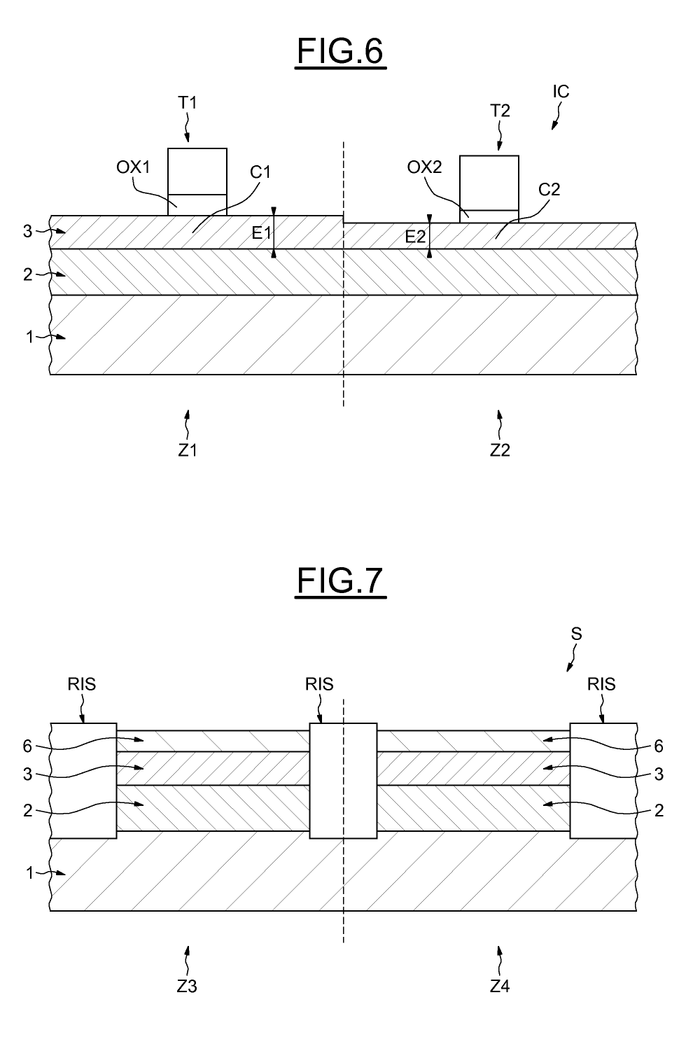

In order to improve the compromise between the electrostatic control and the hot carrier reliability (HCI) of all transistors, in particular transistors with a thick gate oxide, at least one transistor T1 comprising a thick gate oxide may advantageously be formed in the first region Z1 where its conduction channel C1 situated in the semiconductor film 3 is thicker. A transistor T2 comprising a thinner gate dielectric OX2 in the second region Z2 with a thinner conduction channel C2 is then formed (FIG. 6).

By way of example, a transistor with a thick gate oxide, is for example a transistor with an oxide thickness of around 40 Angströms, whereas a conventional transistor with a thin gate oxide has an oxide thickness of around 10 to 15 Angströms.

The process of formation of these transistors is conventional and well known by those skilled in the art.

It should be noted that, in FIG. 6, which is very schematic, insulating regions, comprising for example shallow trenches (STI: Shallow Trench Isolation), isolate between the first and second regions Z1 and Z2 and have intentionally not been illustrated.

FIGS. 7 to 11 illustrate schematically one possible variant of the invention.

FIG. 7 illustrates an initial substrate S of the FDSOI type in which a first region Z3 and a second region Z4 are isolated by insulating regions RIS, for example of the STI type. A semiconductor film 3 situated on a buried insulating layer 2 (BOX) itself on top of a carrier substrate 1, which may for example be a semiconductor well, can again be seen.

The semiconductor film 3 here is conventionally covered by a protection layer 6, for example of the PADOX type, and is partially consumed by this PADOX layer 6. The thickness of the semiconductor film 3 is therefore reduced uniformly over the whole semiconductor film 3.

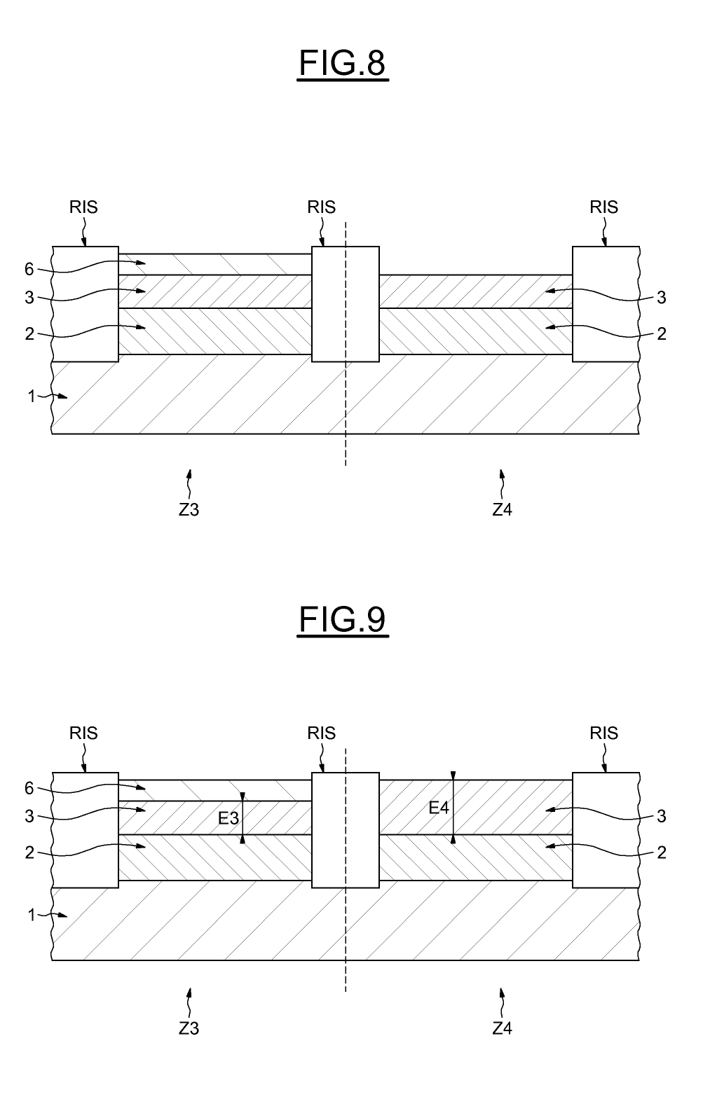

As illustrated in FIG. 8, subsequently, by conventional photolithography, etch mask and an appropriate wet etch, the protection layer 6 on top of the semiconductor film 3 in the second region Z4 is eliminated.

A epitaxy step of the silicon or silicon germanium or alloy of silicon type, conventional and known per se, on the semiconductor film 3 in the second region Z4 may be provided in the step illustrated in FIG. 9, in order to form a thickness E4 of the semiconductor film 3 in the second region Z4 greater than that E3 in the first region Z3.

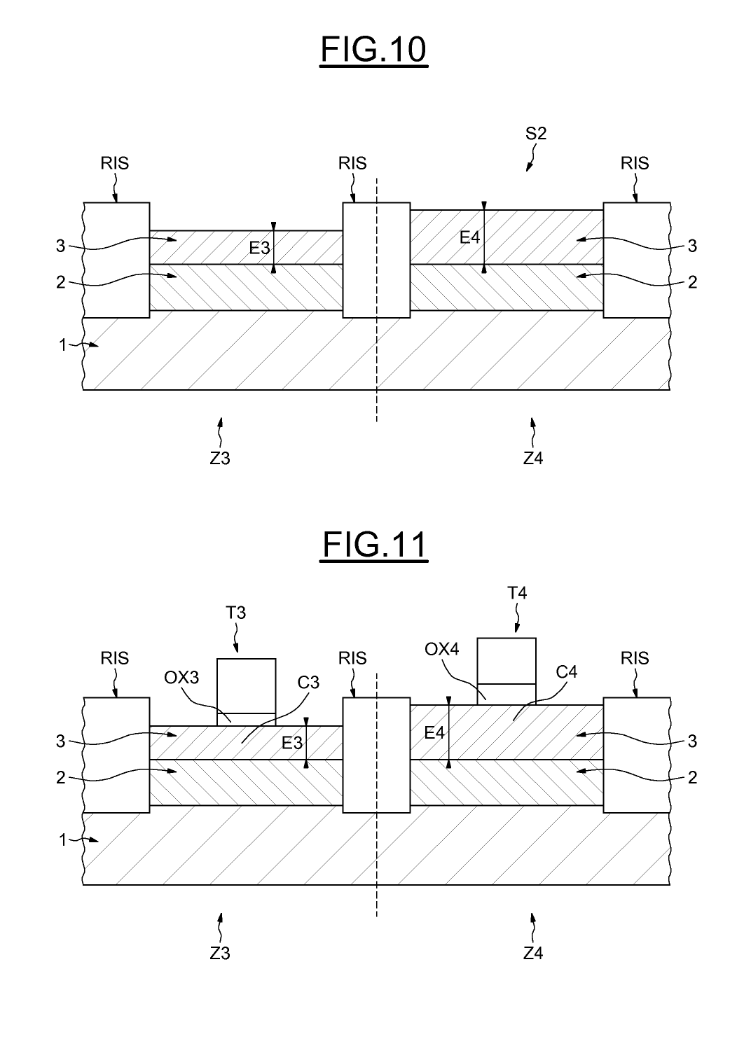

An etching step is subsequently carried out on the semiconductor film 3 so as to remove the rest of the layer 6 situated on top of the semiconductor film 3 having a thickness E3 which is thin in the first region Z3 (FIG. 10).

A substrate S2 of the SOI type is thus obtained whose semiconductor film 3 has different thicknesses E3 and E4 in the various regions Z3 and Z4.

Then, in an analogous manner to what has been described with reference to FIG. 6, a transistor T3 comprising a thin gate dielectric OX3 on the thin film C3 in the first region Z3 and a transistor T4 comprising a thick gate dielectric OX4 on the conduction channel C4 in the second region Z4 are for example formed (FIG. 11).

Thus, with the two variants, an integrated circuit can be formed comprising the substrate of the silicon-on-insulator type S1 or S2, at least a first transistor T2 or T3 with a gate dielectric having a first thickness of dielectric in a region Z2 or Z3 where the semiconductor film has a first thickness of film and at least a second transistor T1 or T4 with a gate dielectric having a second thickness of dielectric greater than the first thickness of dielectric in another region Z1 or Z4 where the semiconductor film has a second thickness of film greater than the first thickness of film.

The invention is not limited to the embodiments and their implementation that have just been described but encompasses all their variants within its scope.

Thus, it would be possible to form more than two different thicknesses of the semiconductor film 3 on the same substrate.

1. A method for the formation of a substrate of the silicon-on-insulator type, comprising:
processing an initial substrate of the silicon-on-insulator type having a semiconductor film on top of a buried insulating layer itself situated on top of a carrier substrate to produce at least one localized modification of a thickness of the semiconductor film so as to form semiconductor film regions having different thicknesses in different substrate regions.

2. The method according to claim 1, wherein processing comprises:
masking the semiconductor film in at least a first substrate region with a mask;
forming in at least a second substrate region at least one protection layer that consumes a part of the semiconductor film in the second substrate region; and
removing the mask and the protection layer.

3. The method according to claim 2, further comprising:
forming a first transistor with a gate dielectric of a first thickness on the semiconductor film in the first substrate region; and
forming a second transistor with a gate dielectric of a second thickness on the semiconductor film in the second substrate region.

4. The method of claim 3, wherein the gate dielectric of the first thickness is thicker than the gate dielectric of the second thickness.

5. The method according to claim 1, wherein producing comprises:
forming a protection layer on the semiconductor film;
removing the protection layer over a first substrate region while leaving the protection layer in place over a second substrate region;
growing by epitaxy of the silicon type on the semiconductor film in the first substrate region to increase a thickness of the semiconductor film in the first substrate region; and
removing the protection layer from over the second substrate region.

6. The method according to claim 5, further comprising:
forming a first transistor with a gate dielectric of a first thickness on the semiconductor film in the first substrate region; and
forming a second transistor with a gate dielectric of a second thickness on the semiconductor film in the second substrate region.

7. The method of claim 6, wherein the gate dielectric of the first thickness is thicker than the gate dielectric of the second thickness.

8. The method according to claim 1, wherein the substrate is of a fully-depleted silicon-on-insulator type.

9. A substrate of a silicon-on-insulator type, comprising:
a semiconductor film having different thicknesses in different substrate regions and resting on a same buried insulating layer itself situated on top of a same carrier substrate.

10. The substrate according to claim 9, wherein the substrate is of a fully-depleted silicon-on-insulator type.

11. The substrate according to claim 10, further comprising an insulation structure between the different substrate regions.

12. An integrated circuit, comprising:
a substrate of the silicon-on-insulator type comprising a semiconductor film having different thicknesses in different substrate regions and resting on a same buried insulating layer itself situated on top of a same carrier substrate;
a first transistor with a first gate dielectric having a first thickness in a first substrate region where the semiconductor film has a first thickness; and
a second transistor with a second gate dielectric having a second thickness in a second substrate region where the semiconductor film has a second thickness,
wherein said second thickness of the second gate dielectric is thicker than the first thickness of the first gate dielectric, and
wherein said second thickness of the semiconductor film is thicker than the first thickness of the semiconductor film.

13. The integrated circuit according to claim 12, wherein the substrate is of a fully-depleted silicon-on-insulator type.

14. The integrated circuit according to claim 12, further comprising an insulation structure between the first and second substrate regions.
